(19) United States
(12) Patent Application Publication
(10) Pub. No.: US 2025/0105107 A1
(43) Pub. Date: Mar. 27, 2025

(54) ELECTRONIC CIRCUIT PACKAGES THAT DEMONSTRATE REDUCED ADHESION TO MOLD FLASH AND METHODS FOR REDUCING ADHESION OF MOLD FLASH TO METAL LEADFRAMES

(71) Applicant: ACULON, INC., SAN DIEGO, CA (US)

(72) Inventors: Donald Cunningham, Dallas, TX (US); ERIC L. BRUNER, LA JOLLA, CA (US); Eric L. Hanson, Carlsbad, CA (US); Andres Hanau, San Diego, CA (US); Majid Monji, Poway, CA (US); Mario Gattuso, La Jolla, CA (US)

(21) Appl. No.: 18/907,676

(22) Filed: Oct. 7, 2024

Related U.S. Application Data
(63) Continuation of application No. PCT/US23/17957, filed on Apr. 7, 2023.
(60) Provisional application No. 63/328,729, filed on Apr. 7, 2022.

(51) Int. Cl. H01L 23/495; H01L 23/00; H01L 23/31

(52) U.S. Cl. CPC H01L 23/49558; H01L 23/3121; H01L 23/49513; H01L 23/49586; H01L 24/48; H01L 24/49; H01L 2224/48175; H01L 2224/49171; H01L 2924/17151

(57) ABSTRACT

Electronic circuit packages are provided comprising: (a) at least one metal leadframe having a surface; (b) a surface treatment coating applied to the surface of the at least one metal leadframe to form at least one coated leadframe; and (c) an encapsulating polymeric layer that is molded over portions of the at least one coated leadframe. The surface treatment coating comprises: (1) a single-layer repellency coating applied to the surface of the at least one metal leadframe; or (2) a two-layer repellency coating comprising: (i) a first layer deposited from an aqueous solution of a metal salt, applied to the surface of the at least one metal leadframe; and (ii) a repellency layer applied to the first layer. Also provided are methods of reducing adhesion of mold flash from epoxy mold compound to a metal leadframe surface during manufacture of an electronic circuit package.

### FIELD OF THE INVENTION

The present application is a continuation of International Patent Application Serial Number PCT/US2023/017957, filed Apr. 7, 2023, titled “Electronic Circuit Packages that Demonstrate Reduced Adhesion to Mold Flash and Methods for Reducing Adhesion of Mold Flash to Metal Leadframes” which published Oct. 12, 2023 as publication number WO 2023/196645 which publication and application are incorporated herein by reference. International Patent Application Serial Number PCT/US2023/017957 claims the benefit of provisional patent application Ser. No. 63/328,729 filed Apr. 7, 2022 titled “Electronic Circuit Packages that Demonstrate Reduced Adhesion to Mold Flash and Methods for Reducing Adhesion of Mold Flash to Metal Leadframes” which application is incorporated herein by reference.

### FIELD OF THE INVENTION

The present invention relates to electronic circuit packages and methods of reducing adhesion of mold flash to a metal leadframe surface during manufacture of an electronic circuit package.

### BACKGROUND OF THE INVENTION

An electronic circuit package, or assembly, comprises many individual components including, for example, resistors, transistors, capacitors, etc. These components are interconnected to form circuits, and circuits are likewise interconnected to form units having specific functions. In microelectronic circuit packages, circuits and units are prepared in packaging levels of increasing scale. The smallest scale packaging levels are typically semiconductor chips housing multiple microcircuits and/or other components. Such chips are usually made from ceramics, silicon, and the like. Intermediate package levels (“chip carriers”) comprising multi-layer substrates may have attached thereto a plurality of small-scale chips housing many microelectronic circuits. The intermediate package levels serve several purposes in the circuit assembly including structural support, transitional integration of the smaller scale microcircuits and circuits to larger scale boards, and the dissipation of heat from the circuit assembly. In turn, these intermediate package levels are themselves attached to larger scale circuit cards, motherboards, and the like.

A leadframe is used as the electrical connection between a semiconductor chip and a printed circuit board (and thus to other electrical components), such as in a flat no-lead package, including quad-flat no-leads (QFN) and dual-flat no-leads (DFN). Leadframes are typically constructed of a base metal such as copper, a copper alloy, iron, or an iron alloy. Copper is preferred because of its corrosion resistance, electrical conductivity and solderability. Leadframes are usually manufactured from a continuous strip of copper or copper metal alloy (optionally plated with additional layers) onto which a pattern is repeatedly stamped or etched comprising a central die pad that multiple inner leads extend out from to outer leads, which form the connection of the package to the board. Then, an adhesive is dispensed onto the die pad, and a semiconductor chip called a die is placed on top and the adhesive is cured. Electrical connections are then made between the top of the semiconductor die and the leads via ultrasonically welded thin gold wires. This assembly is quite fragile, so it is usually protected by encapsulating it in a polymeric layer such as an epoxy molding compound that provides mechanical durability to the assembly. After curing, the assembly is sectioned from the adjacent packages and it is connected to a printed circuit board (PCB) by soldering the leadfingers extending from the assembly to pads on the PCB.

Many molded polymeric encapsulants used for semiconductor and passive component packaging tend to leak through the seal area between the leadframe and the molding tool while the polymer is still liquid and being molded on or around the metal substrate of the active semiconductor or passive component (passives such as resistor, capacity, inductor). Polymer that leaks out and hardens outside the intended molded cavity is called “mold flash”. When the polymer hardens or cures on the exposed surface of the leadframe style semiconductor package solder pads, the polymer effectively contaminates the surface and prevents good solder wetting when the component is ultimately soldered to a printed circuit board assembly. This can cause poor adhesion or connectivity of the component to the assembly and eventual failure of the component.

Another drawback is that once the polymer hardens on the solder pad areas, it is very difficult to remove (“deflash”) and causes the units to be scrapped. Using overly aggressive chemicals or abrasives during the deflash process to remove mold flash also can damage the semiconductor package. Mold flash prevention is especially important for “no lead” semiconductor packages, for example: QFN, MLF, etc., where the solder pad area is very small and any mold flash can yield a scrapped part. Larger panel leadframe formats, which are becoming more common, can increase the instances of yield loss due to mold flash.

In the prior art WO 01/26136 published Apr. 12, 2001 relates to an encapsulation for a microsystem, wherein the encapsulation may serve as a protection against environmental aspects, such as chemical attack, physical attack, fluid penetration and electromagnetic interference.

U.S. Pat. No. 8,860,076 relates to an optical semiconductor sealing curable composition and semiconductors implementing the same.

It would be desirable to provide electronic circuit packages with reduced adhesion to mold flash, and methods of reducing or even preventing mold flash adhesion to the metal surfaces, in turn increasing production yields.

### SUMMARY OF THE INVENTION

Electronic circuit packages are provided comprising: (a) at least one metal leadframe having a surface; (b) a surface treatment coating applied to the surface of the at least one metal leadframe to form at least one coated leadframe; and (c) an encapsulating polymeric layer that is molded over portions of the at least one coated leadframe. The surface treatment coating comprises: (1) a single-layer repellency coating comprising a perfluoropolyether compound applied to the surface of the at least one metal leadframe; or (2) a two-layer repellency coating comprising: (i) a first layer deposited from an aqueous solution of a metal salt, applied to the surface of the at least one metal leadframe; and (ii) a repellency layer applied to the first layer. The electronic circuit packages of the present invention demonstrate reduced adhesion to mold flash.

Also provided are methods of reducing adhesion of mold flash from epoxy mold compound to a metal leadframe surface during manufacture of an electronic circuit package, comprising: (a) applying a surface treatment coating to the surface of the metal leadframe; and subsequently (b) molding the epoxy mold compound as an encapsulating polymeric layer over portions of the metal leadframe. The surface treatment coating comprises: (1) a single-layer repellency coating comprising a perfluoropolyether compound applied to the surface of the metal leadframe; or (2) a two-layer repellency coating comprising: (i) a first layer deposited from an aqueous solution of a metal salt, applied to the surface of the metal leadframe; and (ii) a repellency layer applied to the first layer.

### BRIEF DESCRIPTION OF THE DRAWINGS

FIG. 1 is a schematic cross-sectional view of a conventional electronic circuit package of the prior art, showing mold flash formed from encapsulating polymer leaking out at the lower interface between the molded encapsulating polymer and exposed leadframe.

FIG. 2 is a schematic cross-sectional view of an electronic circuit package according to a first embodiment of the present invention, wherein a surface treatment coating comprising a single-layer repellency coating is applied to the surface of at least one metal leadframe, with an encapsulating polymeric coating layer molded over portions of the coated leadframe(s).

FIG. 3 is a schematic cross-sectional view of an electronic circuit package according to a second embodiment of the present invention, wherein a surface treatment coating comprising a two-layer repellency coating is applied to the surface of at least one metal leadframe, with an encapsulating polymeric coating layer molded over portions of the coated leadframe(s).

### DETAILED DESCRIPTION OF THE INVENTION

Other than in any operating examples, or where otherwise indicated, all numbers expressing quantities of ingredients, reaction conditions and so forth used in the specification and claims are to be understood as being modified in all instances by the term “about.” Accordingly, unless indicated to the contrary, the numerical parameters set forth in the following specification and attached claims are approximations that may vary depending upon the desired properties to be obtained by the present invention. At the very least, and not as an attempt to limit the application of the doctrine of equivalents to the scope of the claims, each numerical parameter should at least be construed in light of the number of reported significant digits and by applying ordinary rounding techniques.

Notwithstanding that the numerical ranges and parameters setting forth the broad scope of the invention are approximations, the numerical values set forth in the specific examples are reported as precisely as possible. Any numerical value, however, inherently contain certain errors necessarily resulting from the standard deviation found in their respective testing measurements.

Also, it should be understood that any numerical range recited herein is intended to include all sub-ranges subsumed therein. For example, a range of “1 to 10” is intended to include all sub-ranges between (and including) the recited minimum value of 1 and the recited maximum value of 10, that is, having a minimum value equal to or greater than 1 and a maximum value of equal to or less than 10.

As used in this specification and the appended claims, the articles “a,” “an,” and “the” include plural referents unless expressly and unequivocally limited to one referent.

The various embodiments and examples of the present invention as presented herein are each understood to be non-limiting with respect to the scope of the invention.

As used in the following description and claims, the following terms have the meanings indicated below:

The terms “on”, “appended to”, “affixed to”, “bonded to”, “adhered to”, or terms of like import means that the designated item, e.g., a coating, component, or layer, is either directly connected to (in contact with) the object surface, or indirectly connected to the object surface, e.g., through one or more other coatings, components, or layers.

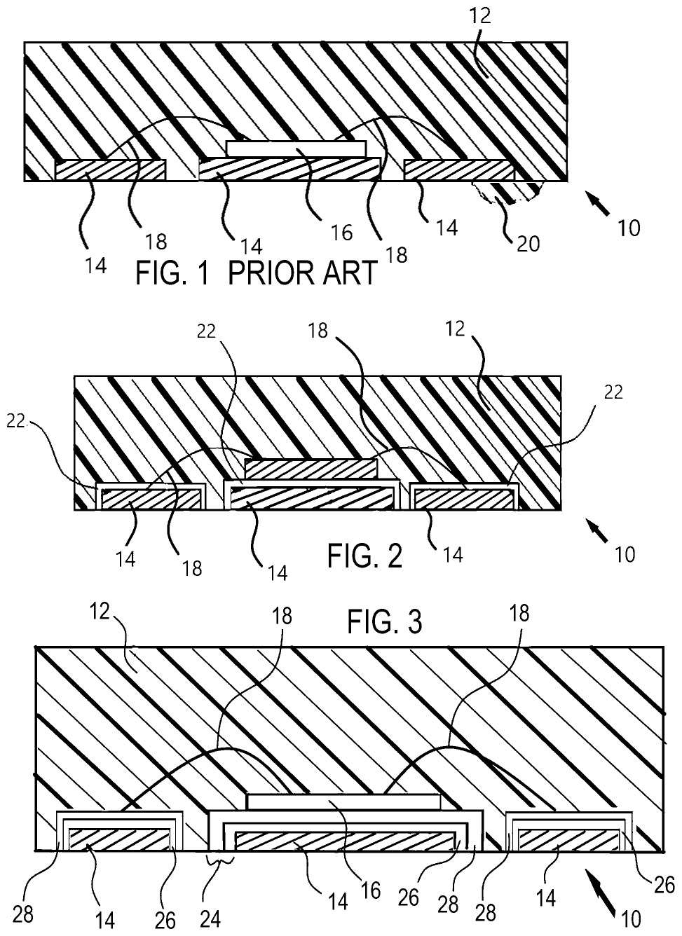

FIG. 1 illustrates a schematic cross-sectional view of an example of a conventional electronic circuit package 10 of the prior art (a wirebonded lead frame QFN style semiconductor package), wherein an encapsulating polymeric layer 12 is molded around various components of the package (comprising one or more lead frames 14, an active chip 16, and connection wires 18). Mold flash 20 formed from encapsulating polymer is shown leaking out at the lower interface between the molded encapsulating polymer layer 12 and exposed leadframe 14.

FIG. 2 illustrates a schematic cross-sectional view of an example of an electronic circuit package 10 according to the present invention (a wirebonded lead frame QFN style semiconductor package), wherein a surface treatment coating comprising a single-layer repellency coating 22 is applied to the surface of at least one metal leadframe 14, and an encapsulating polymeric layer 12 is molded around various components of the package (comprising one or more lead frames 14, an active chip 16, and connection wires 18). The surface treatment coating prevents mold flash from adhering to the metal surfaces, such as leadframes.

FIG. 3 illustrates a schematic cross-sectional view of an example of an electronic circuit package 10 according to the present invention (a wirebonded lead frame QFN style semiconductor package). A surface treatment coating comprising a two-layer repellency coating 24, which in turn comprises a first layer 26 applied to the surface of the at least one metal leadframe 14; and a repellency layer 28 applied to the first layer 26, is applied to the surface of at least one metal leadframe 14, and an encapsulating polymeric layer 12 is molded around various components of the package (comprising one or more lead frames 14, an active chip 16, and connection wires 18). The surface treatment coating prevents mold flash from adhering to the metal surfaces, such as leadframes.

The electronic circuit packages 10 of the present invention comprise (a) at least one metal leadframe 14 having a surface. Materials suitable for use as leadframes typically include a metal such as copper or steel. The copper base metal is often plated with one or more layers of nickel and/or palladium. Gold may also be used as a plating metal but is usually avoided because of cost and because it is not necessary for corrosion resistance. Note that the phrase “and/or” when used in a list is meant to encompass alternative embodiments including each individual component in the list as well as any combination of components. For example, the list “A, B, and/or C” is meant to encompass seven separate embodiments that include A, or B, or C, or A+B, or A+C, or B+C, or A+B+C.

The leadframe 14 is typically in the form of a flat plate having two opposing surfaces, such as would be suitable for use in an electronic circuit assembly as a circuit board.

Prior to application of any coatings, the surface of the leadframe 14 may be cleaned such as by argon plasma treatment or with a solvent such as lonox I3416 or Cybersolv 141-R, both available from Kyzen.

The electronic circuit packages 10 of the present invention further comprise (b) a surface treatment coating applied to the surface of the metal leadframe to form a coated leadframe. Often there are multiple leadframes to be coated. The surface treatment coating may comprise (1) a single-layer repellency coating 22 as shown in FIG. 2 or (2) a two-layer repellency coating 24 as shown in FIG. 3. By “repellency coating” is meant a coating composition that repels polymers such as epoxy or polysiloxane that are typically used as encapsulating polymers for electronic circuit packages. The repellency coating is often hydrophilic; i. e., demonstrates an attraction to water, such that on articles coated with a repellency coating, the contact angle of water is often less than 60 degrees, or less than 40 degrees, or less than 25 degrees.

The single-layer repellency coating 22 usually comprises a perfluoropolyether compound such as one or more of a perfluoropolyether siloxane and perfluoropolyether phosphonic acid. Suitable compositions for use as the single-layer repellency coating 22 are available from Aculon, Inc. as AL-B and OLEO-LT.

The two-layer repellency coating 24 usually comprises (i) a first layer 26 deposited from an aqueous solution of a metal (such as an alkali or alkaline earth metal) salt, applied to the surface of at least one metal leadframe 14. The aqueous solution of metal salt, may partially form an oxide when deposited. Examples of suitable metals salts include, inter alia, sodium silicate. The two-layer repellency coating 24 further comprises (ii) a repellency layer (“second layer”) 28 applied to the first layer 26. The first layer 26 primarily serves as an adhesion layer, or tie layer, between the metal surface being coated and the repellency layer (ii).

The repellency layer 28 used in the two-layer coating may be any of those disclosed above as the single-layer repellency coating 22. More often, the repellency layer (ii) includes coatings deposited from a composition comprising a zwitterionic functional compound such as a betaine. Silanol functional compounds, including monosilanols such as 3-{[dimethyl(3,3-dimethoxysilyl,3-silanol)propyl] ammonio} propane-1-sulfonate are particularly suitable in compositions used to form the repellency layer (ii).

Suitable solvents for use in the single-layer and two-layer repellency coatings may be organic or inorganic. Exemplary organic solvents include alcohols such as methanol, ethanol and propanol, aliphatic hydrocarbons such as hexane, isooctane and decane; ethers, for example, tetrahydrofuran, and dialkylethers such as diethylether. Fluorinated solvents may also be used and include EnSolv NEXT solvents, available from Envirotech International. Inc.; VERTREL solvents available from E. I. DuPont de Nemours; and FLUORINERT, NOVEC, and HFE-7500 fluorosolvents, all available from 3M. Mixtures of solvents may also be used. Often the coating compositions further include water.

Adjuvant materials may be present in any of the above compositions. Examples include fillers, viscosity (rheology) modifying components such as shear thinning or thixotropic compounds, stabilizers such as sterically hindered alcohols and acids, surfactants and anti-static agents. The adjuvants, if present, are individually present in amounts of up to 30 percent by weight based on the non-volatile (solids) content of the composition.

The compositions used to form each of the surface treatment coating layers can be prepared by mixing all of the components at the same time for the respective coating layer with low shear mixing or by combining the ingredients in several steps.

The surface treatment coating comprising the single-layer or two-layer repellency coating may be applied to all or a portion of the surface of at least one metal leadframe. The surface treatment coating can be applied to the leadframe surface by conventional means such as dipping, rolling, spraying, wiping to form a film, jet printing, gravure printing, dispensing such as with a syringe, or pad stamping using an applicator pad saturated with the coating composition. Portions of the leadframe surface that are to remain exposed (for subsequent attachment to other package components such as by soldering) may be masked to prevent application of any coatings to the substrate surface. However, masking is not often practical, and is typically not necessary because a particular benefit of the surface treatment coatings used to prepare the electronic circuit packages of the present invention is that the industry standard mold flash removing process (known as deflash) also removes the surface treatment coating under the mold flash and on the exposed metal areas. No additional removal process for the coating is required. The surface treatment coating is only needed during molding and is readily removed afterward to allow soldering. Thus, any surface treatment coating that is applied to a portion of the leadframe surface that needs to be exposed for soldering may be removed by conventional means during deflash.

After application of the surface treatment coating, any solvent (aqueous or non-aqueous) in the compositions is permitted to evaporate and curing of any reactive functional groups may occur. This can be accomplished by heating to 50-200° C. or by simple exposure to ambient temperature, which is usually from 20-25° C.

The term “cure”, “cured” or similar terms, as used in connection with a cured or curable composition, e.g., a “cured composition” of some specific description, means that at least a portion of any polymerizable and/or crosslinkable components that form the curable composition is polymerized and/or crosslinked. Additionally, curing of a composition refers to subjecting said composition to curing conditions such as those listed above, leading to the reaction of the reactive functional groups of the composition. The term “at least partially cured” means subjecting the composition to curing conditions, wherein reaction of at least a portion of the reactive groups of the composition occurs. The composition can also be subjected to curing conditions such that a substantially complete cure is attained and wherein further curing results in no significant further improvement in physical properties, such as hardness.

The single-layer repellency coating 22 typically has a dry film thickness (DFT) of 1 nm to 10 microns, such as 1 to 100 nm, or 10 to 80 nm, or 10 to 50 nm, or 1 to 10 microns, or, depending on the composition of the coating layer and the method of application to the substrate. For example, a spray-applied composition may have a dry film thickness of 1 to 100 nm, such as 2 to 50 nm, or 2 to 20 nm, or 5 to 50 nm, or 5 to 20 nm.

In the two-layer repellency coating, the first layer (i) typically has a dry film thickness (DFT) of 5 nm to 50 nm, such as 10 to 25 nm. The second layer (ii) typically has a dry film thickness (DFT) of 1 nm to 20 nm, such as 2 to 15 nm or 5 to 10 nm.

The electronic circuit packages of the present invention further comprise (c) an encapsulating polymeric layer 12, molded over portions of the coated leadframe(s) 14.

The encapsulating polymeric layer 12 is molded from (i. e., formed from) a composition that may comprise a polysiloxane or a polyepoxide (i. e., epoxy). Such compounds are known in the art. The epoxy typically comprises a conventional transfer molded epoxy molding compound.

Electronic circuit packages of the present invention demonstrate reduced adhesion of mold flash to exposed metal, and any necessary deflash processes are much more effective in preventing damage to the package, with increased yield and fewer scrapped units.

The present invention is further drawn to methods of reducing adhesion of mold flash from epoxy mold compound to a metal leadframe surface during manufacture of an electronic circuit package. An exemplary method comprises: (a) applying a surface treatment coating to the surface of the metal leadframe; and subsequently (b) molding the epoxy mold compound as an encapsulating polymeric layer over portions of the metal leadframe. The surface treatment coating may comprise any of the single-or two-layer repellency coatings disclosed above.

The surface treatment coating may be applied by dipping, rolling, spraying, syringe dispensing, stamping, jet printing, wiping, or gravure printing. In certain examples of the present invention, the surface treatment coating may be applied to one or more leadframes to be used in the electronic circuit package prior to attachment of the leadframe(s) to other components of the package (e. g., chips and passives such as resistor, capacitor, inductor) and assembly of the package. Alternatively, the components may be assembled together, including attachment of passives and wire connections, and then all of the components coated with the surface treatment coating. Any surface treatment coating that is applied to a portion of the surface(s) that needs to be exposed may be removed by conventional means. In other examples of the present invention, the coating may remain in place on all exposed areas of the leadframe(s).

After application of the surface treatment coating and prior to molding the encapsulating poylemric layer over the components, any solvent (aqueous or non-aqueous) in the compositions is permitted to evaporate and curing of any reactive functional groups may occur. This can be accomplished by heating to 50-200° C. or by simple exposure to ambient temperature, which is usually from 20-25° C.

After applying the surface treatment coating to the surface of the metal leadframe(s) and after drying and/or curing of the surface treatment coating, the epoxy mold compound is molded over portions of the metal leadframe(s) and other components as an encapsulating polymeric layer.

By decreasing or even preventing adhesion of the mold flash to the leadframe metal in the method of the present invention, standard deflash processes can be nearly 100% effective in mold flash removal.

Whereas particular embodiments of this invention have been described above for purposes of illustration, it will be evident to those skilled in the art that numerous variations of the details of the present invention may be made without departing from the scope of the invention as defined in the appended claims.

What is claimed is:

1. An electronic circuit package comprising:
(a) at least one metal leadframe having a surface;
(b) a surface treatment coating applied to the surface of the at least one metal leadframe to form at least one coated leadframe; and
(c) an encapsulating polymeric layer that is molded over portions of the at least one coated leadframe;
wherein the surface treatment coating comprises:
(1) a single-layer repellency coating comprising a perfluoropolyether compound applied to the surface of the at least one metal leadframe; or
(2) a two-layer repellency coating comprising:
(i) a first layer deposited from an aqueous solution of a metal salt, applied to the surface of the at least one metal leadframe; and
(ii) a repellency layer applied to the first layer, wherein the repellency layer (ii) comprises a zwitterionic-functional compound.

2. The electronic circuit package of claim 1 wherein the surface treatment coating (b) comprises the single-layer repellency coating (1).

3. The electronic circuit package of claim 2 wherein the perfluoropolyether compound comprises one or more of a perfluoropolyether siloxane and perfluoropolyether phosphonic acid.

4. The electronic circuit package of claim 1, wherein the surface treatment coating (b) comprises the two-layer repellency coating (2).

5. The electronic circuit package of claim 4 wherein the first layer (i) demonstrates a dry film thickness of 5 to 50 nm.

6. The electronic circuit package of claim 4, wherein the zwitterionic-functional compound comprises 3-{[dimethyl(3,3-dimethoxysilyl,3-silanol)propyl] ammonio} propane-1-sulfonate.

7. The electronic circuit package of claim 6 wherein the first layer (i) demonstrates a dry film thickness of 5 to 50 nm.

8. The electronic circuit package of claim 4, wherein the repellency layer (ii) demonstrates a dry film thickness of 1 to 20 nm.

9. The electronic circuit package of claim 1, wherein the encapsulating polymeric layer (c) comprises an epoxy or a polysiloxane.

10. A method of reducing adhesion of mold flash from epoxy mold compound to a metal leadframe surface during manufacture of an electronic circuit package, comprising:
(a) applying a surface treatment coating to the surface of the metal leadframe; and subsequently
(b) molding the epoxy mold compound as an encapsulating polymeric layer over portions of the metal leadframe;
wherein the surface treatment coating comprises:
(1) a single-layer repellency coating comprising a perfluoropolyether compound applied to the surface of the metal leadframe; or
(2) a two-layer repellency coating comprising:
(i) a first layer deposited from an aqueous solution of a metal salt, applied to the surface of the metal leadframe; and
(ii) a repellency layer applied to the first layer, wherein the repellency layer (ii) comprises a zwitterionic-functional compound.

11. The method of claim 10, wherein the surface treatment coating is applied by dipping, rolling, spraying, syringe dispensing, stamping, jet printing, wiping, or gravure printing.

12. The method of claim 10, wherein the surface treatment coating (b) comprises the single-layer coating (1).

13. The method of claim 12, wherein the perfluoropolyether compound comprises one or more of a perfluoropolyether siloxane and perfluoropolyether phosphonic acid.

14. The method of claim 12, wherein the surface treatment coating is applied to the surface of the metal leadframe by stamping.

15. The method of claim 10, wherein the surface treatment coating (b) comprises the two-layer coating (2).

16. The method of claim 15 wherein the first layer (i) is spray applied to the surface of the metal leadframe and demonstrates a dry film thickness of 5 to 50 nm.

17. The method of claim 15, wherein the zwitterionic-functional compound comprises 3-{[dimethyl(3,3-dimethoxysilyl,3 silanol)propyl] ammonio} propane-1-sulfonate.

18. The method of claim 17, wherein the repellency layer (ii) is spray applied to the first layer (i) and demonstrates a dry film thickness of 2 to 20 nm.

19. The method of claim 15, wherein the repellency layer (ii) is spray applied to the first layer (i) and demonstrates a dry film thickness of 2 to 20 nm.

20. An electronic circuit package comprising:
(a) at least one metal leadframe having a surface;
(b) a surface treatment coating applied to the surface of the at least one metal leadframe to form at least one coated leadframe; and
(c) an encapsulating polymeric layer that is molded over portions of the at least one coated leadframe;
wherein the surface treatment coating comprises a two-layer repellency coating comprising:
(i) a first layer deposited from an aqueous solution of a metal salt, applied to the surface of the at least one metal leadframe, wherein the first layer demonstrates a dry film thickness of 5 to 50 nm.; and
(ii) a repellency layer applied to the first layer, wherein the repellency layer comprises a zwitterionic-functional compound.
